(19) United States
(12) Patent Application Publication
(10) Pub. No.: US 2026/0314503 A1
(43) Pub. Date: Oct. 8, 2026

(54) SEMICONDUCTOR DEVICE AND METHOD FOR PRODUCING SEMICONDUCTOR DEVICE

(71) Applicant: Resonac Corporation, Tokyo (JP)

(72) Inventors: Kei ITAGAKI, Tokyo (JP); Kanami NAKAMURA, Tokyo (JP); Yuma ARAI, Tokyo (JP)

(21) Appl. No.: 19/479,016

(22) PCT Filed: Jul. 16, 2024
(86) PCT No.: PCT/JP2024/025532

§ 371 Date: Oct. 27, 2025

(30) Foreign Application Priority Data
Jul. 21, 2023 (JP) 2023-119154

(51) Int. Cl. H10W 90/28; H10B 80/00; H10D 80/30; H10W 42/00; H10W 72/00; H10W 90/00

(52) U.S. Cl. CPC H10W 90/28; H10W 42/121; H10W 72/07302; H10W 72/07338; H10W 90/732; H10W 90/734; H10B 80/00; H10D 80/30

(57) ABSTRACT

A semiconductor device includes: a substrate; a first semiconductor chip having a rectangular shape and disposed over the substrate; a plurality of spacers disposed around the first semiconductor chip over the substrate; a second semiconductor chip facing the substrate to cover the first semiconductor chip; and an adhesive layer provided on a surface of the second semiconductor chip to face the first semiconductor chip, and bonded to the first semiconductor chip and the plurality of spacers, in which the plurality of spacers include a first main spacer and a second main spacer disposed on both sides of the first semiconductor chip in a longitudinal direction of the first semiconductor chip, and a first additional spacer and a second additional spacer disposed on both sides of the first semiconductor chip in a lateral direction of the first semiconductor chip.

### TECHNICAL FIELD

The present disclosure relates to a semiconductor device having a dolmen structure and a method for producing a semiconductor device.

### BACKGROUND ART

In recent years, in the field of semiconductor devices, high integration, miniaturization, and high speed are required. As an aspect of a semiconductor device, a structure in which a semiconductor chip is stacked on a controller chip disposed on a substrate has attracted attention. For example, Patent Literature 1 discloses a semiconductor device having a dolmen structure including a substrate, a first semiconductor chip disposed on a surface of the substrate, a plurality of spacers disposed on the surface of the substrate and around the first semiconductor chip, a second semiconductor chip disposed over the first semiconductor chip, and an adhesive layer sandwiched between the second semiconductor chip, the first semiconductor chip, and the plurality of spacers. In this semiconductor device, the first semiconductor chip and the second semiconductor chip are bonded via the adhesive layer, and the plurality of spacers are disposed only on both sides of the first semiconductor chip in the longitudinal direction of the second semiconductor chip.

### CITATION LIST

### Patent Literature

Patent Literature 1: International Publication WO 2020/218526

### SUMMARY OF INVENTION

### Technical Problem

The present inventors conducted a detailed analysis of a semiconductor device produced using a rectangular (oblong) first semiconductor chip, and found that voids had occurred between the first semiconductor chip and an adhesive layer.

Therefore, an object of the present disclosure is to provide a semiconductor device and a method for producing the semiconductor device capable of suppressing occurrence of a void between the first semiconductor chip and the adhesive layer.

### Solution to Problem

As a result of further intensive studies on the above-described problem, the present inventors have obtained the following findings. First, a first semiconductor chip having a rectangular shape and a pair of spacers disposed on both sides of the first semiconductor chip in a longitudinal direction of the first semiconductor chip were bonded onto a substrate, and an adhesive layer was laminated onto one surface of a second semiconductor chip. Next, the second semiconductor chip was bonded to surfaces of the first semiconductor chip and the pair of spacers via the adhesive layer such that the first semiconductor chip was covered with the second semiconductor chip, and the adhesive layer was cured, to produce a semiconductor device. Thereafter, as a result of analyzing the semiconductor device using an ultrasonic microscope, a void extending in the longitudinal direction of the first semiconductor chip at the central portion in the lateral direction of the first semiconductor chip was found between the first semiconductor chip and the adhesive layer.

From the position and shape of the found void, it is presumed that the void occurred for the following reason. That is, since the adhesive layer is laminated onto the second semiconductor chip, the shape retainability of the adhesive layer is improved. In addition, the extension length of the second semiconductor chip and the length of the adhesive layer are not significantly longer than that of the first semiconductor chip in the lateral direction of the first semiconductor chip. Therefore, conventionally, it has been considered that the second semiconductor chip and the adhesive layer do not sag downward toward the substrate at both sides in the lateral direction of the first semiconductor chip. However, in practice, since the length of the first semiconductor chip in the longitudinal direction is longer than the length of the first semiconductor chip in the lateral direction, the second semiconductor chip and the adhesive layer have tended to sag downward toward the substrate even at both sides of the first semiconductor chip in the lateral direction. It is presumed that due to such downward sagging of the second semiconductor chip and the adhesive layer, the adhesive layer lifts off from the first semiconductor chip at the central portion of the first semiconductor chip in the lateral direction, and a void extending in the longitudinal direction of the first semiconductor chip occurs between the first semiconductor chip and the adhesive layer at the central portion of the first semiconductor chip in the lateral direction.

From such results, it has been found that by disposing spacers also on both sides of the first semiconductor chip in the lateral direction, it is possible to suppress downward sagging of the second semiconductor chip and the adhesive layer toward the substrate at both sides of the first semiconductor chip in the lateral direction, and as a result, it is possible to suppress occurrence of a void between the first semiconductor chip and the adhesive layer. The present disclosure has been made based on the above-described findings.

That is, a semiconductor device according to the present disclosure includes: a substrate; a first semiconductor chip having a rectangular shape and disposed over the substrate; a plurality of spacers disposed around the first semiconductor chip over the substrate; a second semiconductor chip facing the substrate to cover the first semiconductor chip; and an adhesive layer provided on a surface of the second semiconductor chip to face the first semiconductor chip, and bonded to the first semiconductor chip and the plurality of spacers, in which the plurality of spacers include a first main spacer and a second main spacer disposed on both sides of the first semiconductor chip in a longitudinal direction of the first semiconductor chip, and a first additional spacer and a second additional spacer disposed on both sides of the first semiconductor chip in a lateral direction of the first semiconductor chip.

In this semiconductor device, not only the first main spacer and the second main spacer are disposed on both sides of the first semiconductor chip in the longitudinal direction of the first semiconductor chip, but the first additional spacer and the second additional spacer are also disposed on both sides of the first semiconductor chip in the lateral direction of the first semiconductor chip. Therefore, during the production of the semiconductor device, it is possible to minimize not only downward sagging of the second semiconductor chip and the adhesive layer toward the substrate at both sides of the first semiconductor chip in the longitudinal direction, but also downward sagging of the second semiconductor chip and the adhesive layer toward the substrate at both sides of the first semiconductor chip in the lateral direction. As a result, it is possible to suppress the occurrence of a void between the first semiconductor chip and the adhesive layer.

In the above-described semiconductor device, a height of each of the first additional spacer and the second additional spacer with respect to the substrate may be equal to or higher than a height of the first semiconductor chip with respect to the substrate. In this semiconductor device, since the height of each of the first additional spacer and the second additional spacer with respect to the substrate is equal to or higher than the height of the first semiconductor chip with respect to the substrate, it is possible to further suppress the occurrence of a void between the first semiconductor chip and the adhesive layer.

In the above-described semiconductor device, the height of each of the first additional spacer and the second additional spacer with respect to the substrate may be higher than the height of the first semiconductor chip with respect to the substrate. In this semiconductor device, since the height of each of the first additional spacer and the second additional spacer with respect to the substrate is higher than the height of the first semiconductor chip with respect to the substrate, it is possible to yet further suppress the occurrence of a void between the first semiconductor chip and the adhesive layer.

In the above-described semiconductor device, a length of each of the first additional spacer and the second additional spacer in the longitudinal direction may be 80% or more and 120% or less of a length of the first semiconductor chip in the longitudinal direction. In this semiconductor device, since the length of each of the first additional spacer and the second additional spacer in the longitudinal direction is 80% or more and 120% or less of the length of the first semiconductor chip in the longitudinal direction, it is possible to appropriately minimize downward sagging of the second semiconductor chip and the adhesive layer toward the substrate at both sides of the first semiconductor chip in the lateral direction during the production of the semiconductor device. As a result, it is possible to yet further suppress the occurrence of a void between the first semiconductor chip and the adhesive layer.

In the above-described semiconductor device, a separation distance between the first semiconductor chip and each of the first additional spacer and the second additional spacer may be shorter than a separation distance between the first semiconductor chip and each of the first main spacer and the second main spacer. In this semiconductor device, since the separation distance between the first semiconductor chip and each of the first additional spacer and the second additional spacer is shorter than the separation distance between the first semiconductor chip and each of the first main spacer and the second main spacer, the first additional spacer and the second additional spacer can be easily disposed between the substrate and the second semiconductor chip even in a case where the second semiconductor chip is short in the lateral direction.

In the above-described semiconductor device, the first additional spacer and the second additional spacer extend beyond the second semiconductor chip in the lateral direction in plan view. In this semiconductor chip, since the first additional spacer and the second additional spacer extend beyond the second semiconductor chip in the lateral direction in plan view, the first additional spacer and the second additional spacer can be easily disposed between the substrate and the second semiconductor chip even in a case where the second semiconductor chip is short in the lateral direction.

A method for producing a semiconductor device according to the present disclosure includes: a step of bonding, onto a substrate, a first semiconductor chip having a rectangular shape, a first main spacer and a second main spacer disposed on both sides of the first semiconductor chip in a longitudinal direction of the first semiconductor chip, and a first additional spacer and a second additional spacer disposed on both sides of the first semiconductor chip in a lateral direction of the first semiconductor chip; a step of laminating an adhesive layer in an uncured state onto one surface of a second semiconductor chip; a step of bonding the second semiconductor chip to surfaces of the first semiconductor chip, the first main spacer, the second main spacer, the first additional spacer, and the second additional spacer via the adhesive layer such that the first semiconductor chip is covered with the second semiconductor chip; and a step of curing the adhesive layer.

In this method for producing a semiconductor device of the present disclosure, a semiconductor device is provided in which not only the first main spacer and the second main spacer are disposed on both sides of the first semiconductor chip in the longitudinal direction of the first semiconductor chip, but the first additional spacer and the second additional spacer are also disposed on both sides of the first semiconductor chip in the lateral direction of the first semiconductor chip. Therefore, it is possible to minimize not only downward sagging of the second semiconductor chip and the adhesive layer toward the substrate at both sides of the first semiconductor chip in the longitudinal direction, but also downward sagging of the second semiconductor chip and the adhesive layer toward the substrate at both sides of the first semiconductor chip in the lateral direction. As a result, it is possible to suppress the occurrence of a void between the first semiconductor chip and the adhesive layer.

### Advantageous Effects of Invention

According to the present disclosure, it is possible to suppress the occurrence of a void between the first semiconductor chip and the adhesive layer.

### BRIEF DESCRIPTION OF DRAWINGS

FIG. 1 is a schematic plan view illustrating a semiconductor device according to the present disclosure.

FIG. 2 is a schematic cross-sectional view taken along line II-II in FIG. 1.

FIG. 3 is a schematic cross-sectional view taken along line III-III in FIG. 1.

FIG. 4 is a schematic plan view illustrating a method for producing a semiconductor device according to the present disclosure.

FIG. 5 is a schematic cross-sectional view taken along line V-V in FIG. 4.

FIG. 6 is a schematic cross-sectional view taken along line VI-VI in FIG. 4.

FIG. 7 is a schematic plan view illustrating the method for producing a semiconductor device according to the present disclosure.

FIG. 8 is a schematic cross-sectional view taken along line VIII-VIII in FIG. 7.

FIG. 9 is a schematic cross-sectional view taken along line IX-IX in FIG. 7.

FIG. 10 is a schematic plan view illustrating a semiconductor device of a comparative example.

FIG. 11 is a schematic cross-sectional view taken along line XI-XI in FIG. 10.

FIG. 12 is a schematic plan view illustrating a semiconductor device of an example.

FIG. 13 is a schematic plan view illustrating a semiconductor device of a comparative example.

FIG. 14 is SAM photographs of semiconductor devices of Examples 1 to 6 and Comparative Examples 1 to 6.

FIG. 15 is SAM photographs of semiconductor devices of Examples 7 to 15.

### DESCRIPTION OF EMBODIMENTS

Hereinafter, embodiments of the present disclosure will be described in detail with reference to the drawings. However, the present disclosure is not limited to the following embodiments. Note that, in the drawings, the same or corresponding parts are denoted by the same reference signs, and redundant description will be omitted. In the present specification, the term “layer” includes not only a structure in which a layer is formed over the entire surface, but also a structure in which a layer is formed partially, when observed in a plan view. In the present specification, the term “step” includes not only an independent step but also a step that cannot be clearly distinguished from other steps as long as an intended action of the step is achieved. In addition, a numerical range using “to” indicates a range including numerical values described before and after “to” as a minimum value and a maximum value.

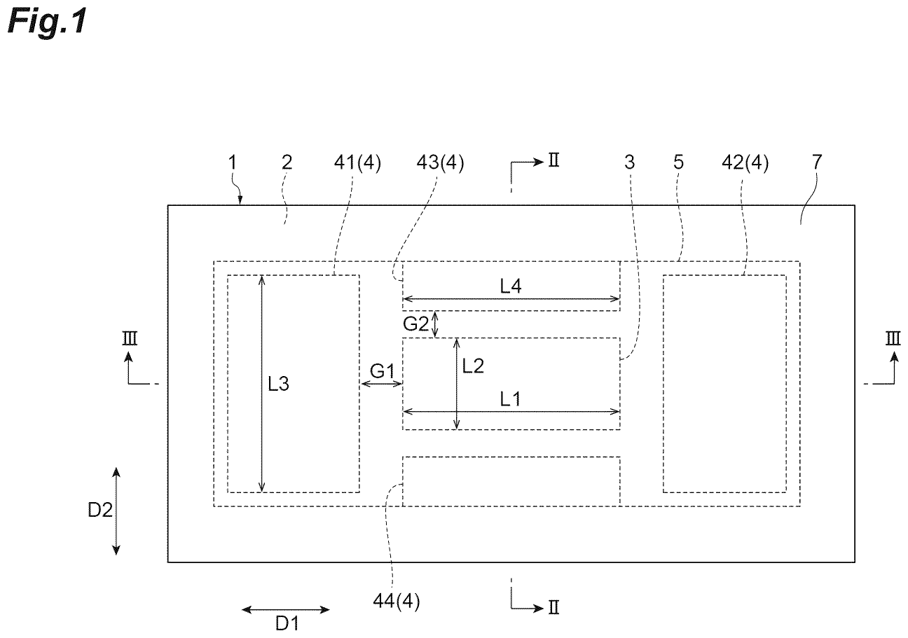

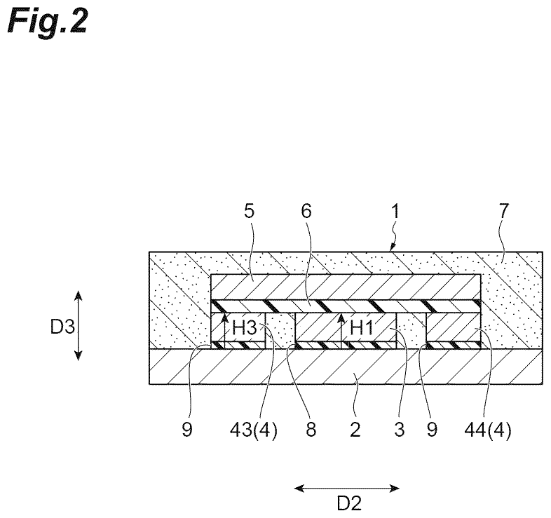

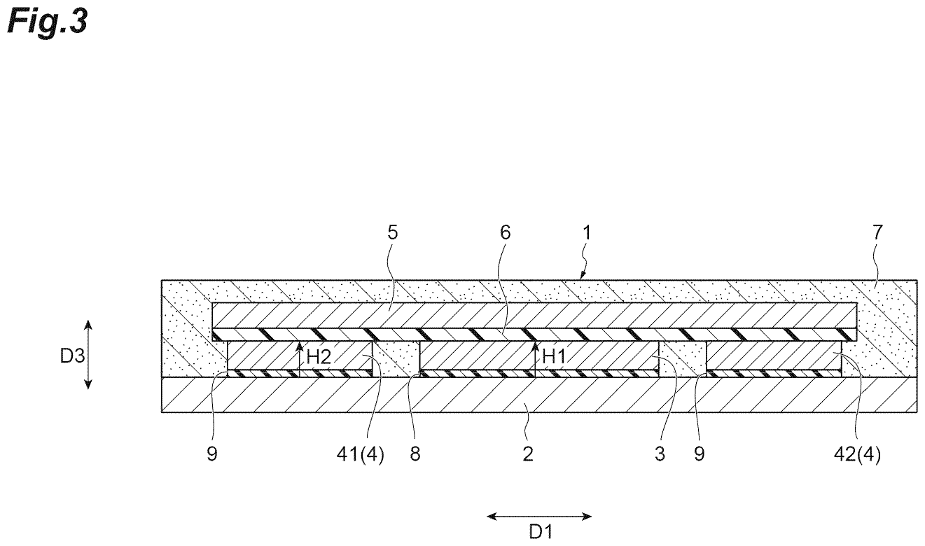

FIG. 1 is a schematic plan view illustrating a semiconductor device according to the present disclosure. FIG. 2 is a schematic cross-sectional view taken along line II-II in FIG. 1. FIG. 3 is a schematic cross-sectional view taken along line III-III in FIG. 1. A semiconductor device 1 illustrated in FIGS. 1 to 3 is configured as a memory semiconductor package such as a NAND flash memory. As illustrated in FIGS. 1 to 3, the semiconductor device 1 includes a substrate 2, a rectangular (oblong) controller chip (first semiconductor chip) 3 disposed over the substrate 2, a plurality of spacers 4 disposed around the controller chip 3 over the substrate 2, a memory chip (second semiconductor chip) 5 facing the substrate 2 to cover the controller chip 3, and an adhesive layer 6 provided on a surface 5a of the memory chip to face the controller chip 3 and bonded to the controller chip 3 and the plurality of spacers 4. In addition to these components, the semiconductor device 1 includes a conductive member (not illustrated) that electrically connects an electrode (not illustrated) of the substrate 2 to each of the controller chip 3 and the memory chip 5. The controller chip 3 and the memory chip 5 are encapsulated by an encapsulation material 7 provided on the substrate 2. The encapsulation material 7 may contain, for example, an epoxy resin. The constituent material of the encapsulation material 7 may include a filler, a curing agent, a curing accelerator, and the like. In addition, a colorant, a mold release agent, a modifier, a flame retardant, and the like may be included as necessary.

The substrate 2 is, for example, an organic substrate. The substrate 2 may be a metal substrate such as a lead frame.

The controller chip 3 is bonded to the substrate 2 by an adhesive layer 8. The controller chip 3 is electrically connected to the electrode of the substrate 2 via the conductive member. The adhesive layer 8 is formed of, for example, a cured product of a thermosetting resin composition, and is formed using a die attach film (DAF). The adhesive layer 8 has a thickness of, for example, about 5 to 25 μm. The controller chip 3 is formed in a rectangular shape (oblong shape) in plan view. That is, the controller chip 3 has a long side and a short side. A length L1 of the controller chip 3 in a longitudinal direction D1 is, for example, about 2.0 to 10.0 mm. A length L2 of the controller chip 3 in a lateral direction D2 is, for example, about 1.0 to 8.0 mm. A height H1 of the controller chip 3 with respect to the substrate 2 is, for example, about 30 to 90 μm. The height H1 of the controller chip 3 with respect to the substrate 2 is also the total thickness of the adhesive layer 8 and controller chip 3. The total thickness of the adhesive layer 8 and controller chip 3 is a dimension in a facing direction D3 between the substrate 2 and the memory chip 5. The thickness of the controller chip 3 is, for example, about 5 to 85 μm.

The plurality of spacers 4 are members for supporting the memory chip 5 and forming a space around the memory chip 5. The plurality of spacers 4 are disposed apart from the memory chip 5. Each of the plurality of spacers 4 is formed of, for example, a cured product of a thermosetting resin composition. The plurality of spacers 4 are bonded to the substrate 2 via an adhesive layer 9. The adhesive layer 9 is formed of, for example, a cured product of a thermosetting resin composition, and is formed using a die attach film (DAF). The thickness of the adhesive layer 9 is, for example, about the same as the thickness of the adhesive layer 8.

The plurality of spacers 4 include a first main spacer 41 and a second main spacer 42 disposed on both sides of the controller chip 3 in the longitudinal direction D1 of the controller chip 3, and include a first additional spacer 43 and a second additional spacer 44 disposed on both sides of the controller chip 3 in the lateral direction D2 of the controller chip 3.

The first main spacer 41 is a spacer 4 disposed on one side of the controller chip 3 in the longitudinal direction D1. The second main spacer 42 is a spacer 4 disposed on the other side of the controller chip 3 in the longitudinal direction D1. The first additional spacer 43 is a spacer 4 disposed on one side of the controller chip 3 in the lateral direction D2. The second additional spacer 44 is a spacer 4 disposed on the other side of the controller chip 3 in the lateral direction D2.

The first main spacer 41 and the second main spacer 42 have, for example, the same shape. The disposition of the first main spacer 41 and the second main spacer 42 with respect to the controller chip 3 is the same, for example, except that the first main spacer 41 and the second main spacer 42 are disposed on the opposite sides of the controller chip 3 in the longitudinal direction D1. A separation distance G1 between the controller chip 3 and each of the first main spacer 41 and the second main spacer 42 in the longitudinal direction D1 is, for example, about 0.2 to 2.0 mm. For example, the first main spacer 41 and the second main spacer 42 extend beyond both sides of the controller chip 3 in the lateral direction D2 when viewed from the longitudinal direction D1. A length L3 of the first main spacer 41 and the second main spacer 42 in the lateral direction D2 is, for example, about 180% to 360% of the length L2 of the controller chip 3 in the lateral direction D2. A height H2 of each of the first main spacer 41 and the second main spacer 42 with respect to the substrate 2 is, for example, about 30 to 90 μm. The height H2 of each of the first main spacer 41 and the second main spacer 42 with respect to the substrate 2 is also the total thickness of the adhesive layer 9 and each of the first main spacer 41 and the second main spacer 42. The total thickness of the adhesive layer 9 and each of the first main spacer 41 and the second main spacer 42 is a dimension in the facing direction D3. The thickness of each of the first main spacer 41 and the second main spacer 42 is, for example, about 5 to 85 μm.

The first additional spacer 43 and the second additional spacer 44 have, for example, the same shape. The disposition of the first additional spacer 43 and the second additional spacer 44 with respect to the controller chip 3 is the same, for example, except that the first additional spacer 43 and the second additional spacer 44 are disposed on the opposite sides of the controller chip 3 in the lateral direction D2. A separation distance G2 between the controller chip 3 and each of the first additional spacer 43 and the second additional spacer 44 in the lateral direction D2 is, for example, about 0.2 to 1.0 mm. The separation distance G2 between the controller chip 3 and each of the first additional spacer 43 and the second additional spacer 44 in the lateral direction D2 is shorter than the separation distance G1 between the controller chip 3 and each of the first main spacer 41 and the second main spacer 42 in the longitudinal direction D1, for example. A length L4 of each of the first additional spacer 43 and the second additional spacer 44 in the longitudinal direction D1 is, for example, about 80% to 120% of the length L1 of the controller chip 3 in the longitudinal direction D1. The length L4 of each of the first additional spacer 43 and the second additional spacer 44 in the longitudinal direction D1 is, for example, the same as the length L1 of the controller chip 3 in the longitudinal direction D1. In addition, a position of each of the first additional spacer 43 and the second additional spacer 44 in the longitudinal direction D1 may be, for example, the same as the position of the controller chip 3 in the longitudinal direction D1. A height H3 of each of the first additional spacer 43 and the second additional spacer 44 with respect to the substrate 2 is, for example, about 30 to 90 μm. The height H3 of each of the first additional spacer 43 and the second additional spacer 44 with respect to the substrate 2 is also the total thickness of the adhesive layer 9 and each of the first additional spacer 43 and the second additional spacer 44. The total thickness of the adhesive layer 9 and each of the first additional spacer 43 and the second additional spacer 44 is a dimension in the facing direction D3. The thickness of each of the first additional spacer 43 and the second additional spacer 44 is, for example, about 5 to 85 μm.

The memory chip 5 is electrically connected to an electrode of the substrate 2 via a conductive member. The memory chip 5 is formed in a rectangular shape (oblong shape) in plan view. That is, the memory chip 5 has a long side and a short side similarly to the controller chip 3. The longitudinal direction of the memory chip 5 is the same direction as the longitudinal direction D1 of the controller chip 3, and the lateral direction of the memory chip 5 is the same direction as the lateral direction D2 of the controller chip 3. The memory chip 5 is formed to cover the entirety of the controller chip 3 and at least a part of each of the plurality of spacers 4 in plan view. In plan view, the first additional spacer 43 and the second additional spacer 44 may extend beyond the memory chip 5 in the lateral direction D2, or may not extend beyond the memory chip 5 in the lateral direction D2. In a case where the memory chip 5 is short in the lateral direction D2, it is preferable that the first additional spacer 43 and the second additional spacer 44 extend beyond the memory chip 5 in the lateral direction D2 in plan view from the viewpoint of facilitating disposition of the first additional spacer 43 and the second additional spacer 44.

The adhesive layer 6 is formed of, for example, a cured product of a thermosetting resin composition, and is formed using a die attach film (DAF). The adhesive layer 6 has a thickness of, for example, about to 80 μm.

In the semiconductor device 1 configured as described above, the controller chip 3, the plurality of spacers 4, the memory chip 5, and the adhesive layer 6 form a dolmen structure on the substrate 2.

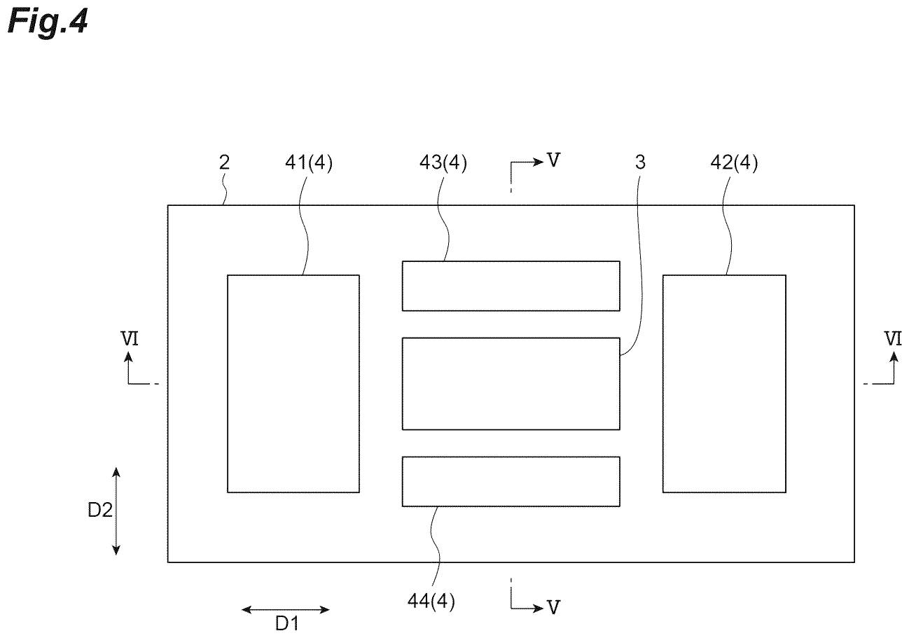

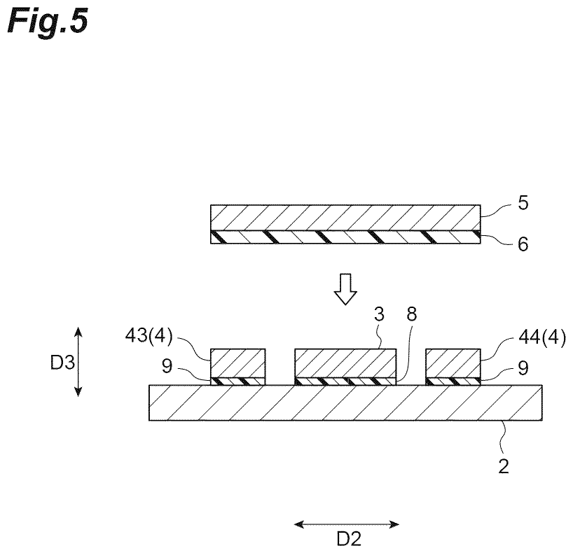

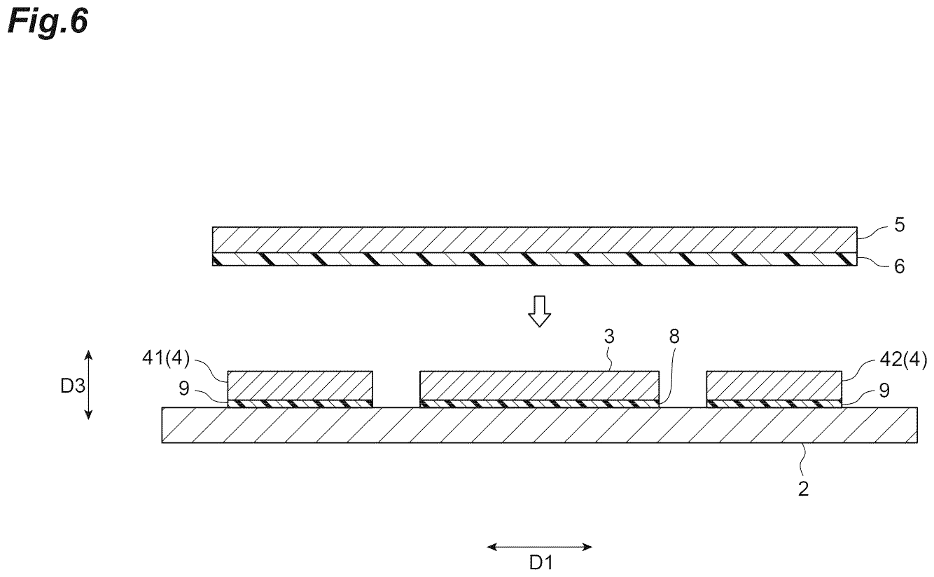

FIG. 4 is a schematic plan view illustrating a method for producing a semiconductor device according to the present disclosure. FIG. 5 is a schematic cross-sectional view taken along line V-V in FIG. 4. FIG. 6 is a schematic cross-sectional view taken along line VI-VI in FIG. 4. As illustrated in FIGS. 4 to 6, in the production of the semiconductor device 1, first, a step of bonding, onto the substrate 2, the controller chip 3 having a rectangular shape, the first main spacer 41 and the second main spacer 42 disposed on both sides of the controller chip 3 in the longitudinal direction D1 of the controller chip 3, and the first additional spacer 43 and the second additional spacer 44 disposed on both sides of the controller chip 3 in the lateral direction D2 of the controller chip 3 is performed. In addition, a step of laminating the adhesive layer 6 in an uncured state on one surface of the memory chip is performed. Any of these steps may be performed first, or these steps may be performed in parallel.

The controller chip 3 is bonded to the substrate 2 with the adhesive layer 8 sandwiched therebetween. That is, the controller chip 3 is disposed over the substrate 2 via the adhesive layer 8 in an uncured state, and the adhesive layer 8 is cured by applying heat to the adhesive layer 8. As a result, the controller chip 3 is bonded to the substrate 2 via the adhesive layer 8. Note that the disposition of the controller chip 3 over the substrate 2 via the adhesive layer 8 in an uncured state and the application of heat to the adhesive layer 8 can be performed by known methods. Thus, the details will not be described herein.

The first main spacer 41, the second main spacer 42, the first additional spacer 43, and the second additional spacer 44 are bonded to the substrate 2 via the adhesive layer 9. That is, the first main spacer 41, the second main spacer 42, the first additional spacer 43, and the second additional spacer 44 are disposed over the substrate 2 via the adhesive layer 9 in an uncured state, and the adhesive layer 9 is cured by applying heat to the adhesive layer 9. As a result, the first main spacer 41, the second main spacer 42, the first additional spacer 43, and the second additional spacer 44 are bonded to the substrate 2 via the adhesive layer 9. The disposition of the first main spacer 41, the second main spacer 42, the first additional spacer 43, and the second additional spacer 44 over the substrate 2 via the adhesive layer 9 in an uncured state and the application of heat to the adhesive layer 9 can be performed by known methods. Thus, the details will not be described herein.

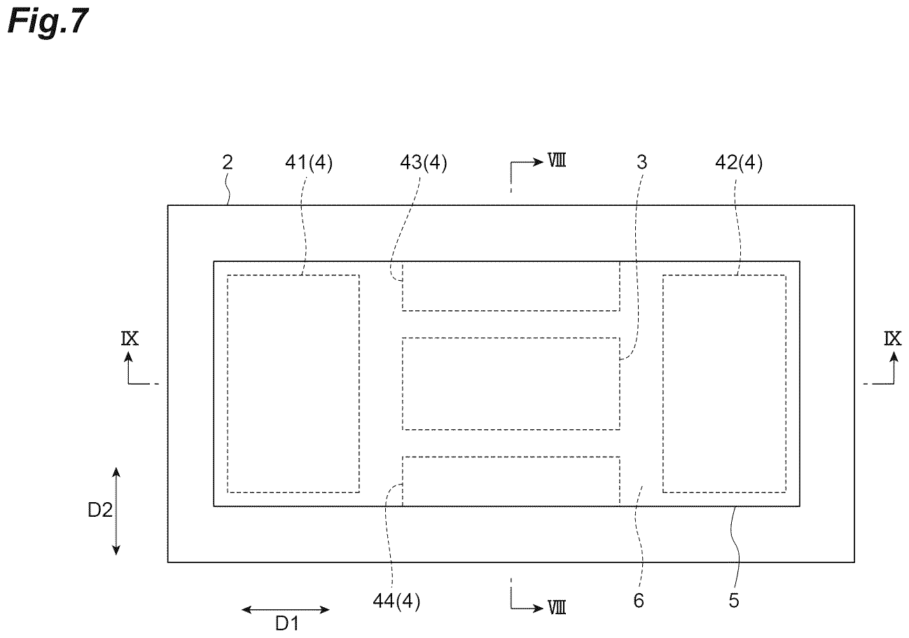

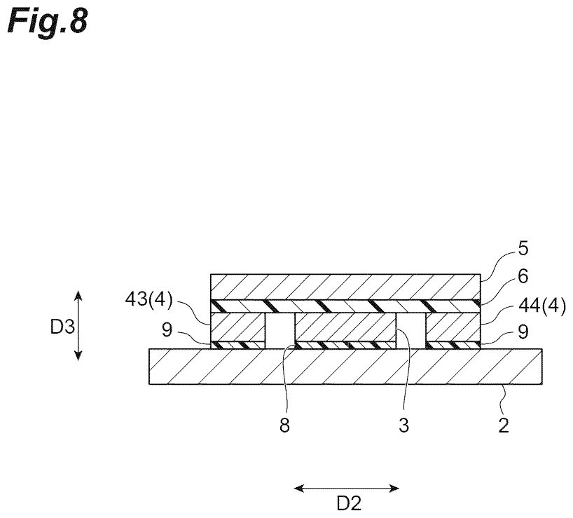

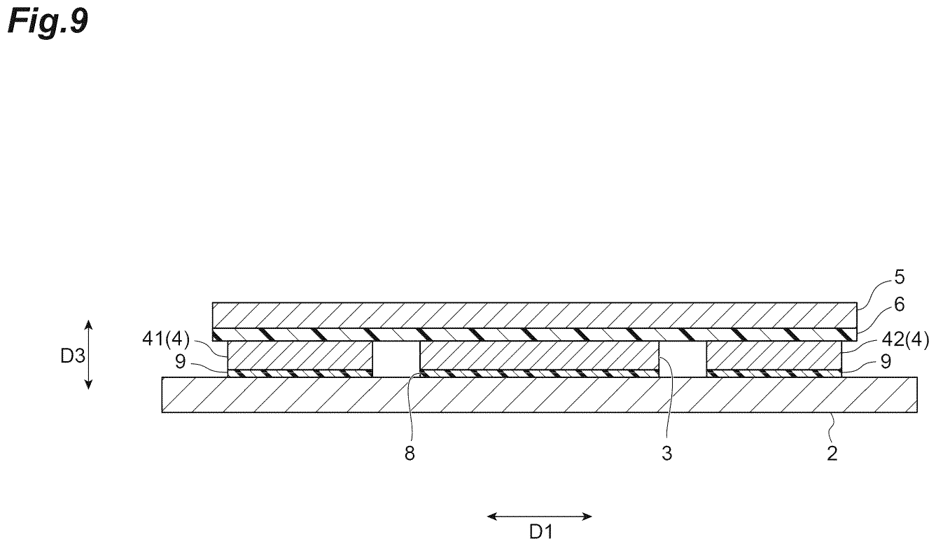

FIG. 7 is a schematic plan view illustrating the method for producing a semiconductor device according to the present disclosure. FIG. 8 is a schematic cross-sectional view taken along line VIII-VIII in FIG. 7. FIG. 9 is a schematic cross-sectional view taken along line IX-IX in FIG. 7. As illustrated in FIGS. 5 to 9, in the production of the semiconductor device 1, next, a step of bonding the memory chip 5 to the surfaces of the controller chip 3, the first main spacer 41, the second main spacer 42, the first additional spacer 43, and the second additional spacer 44 via the adhesive layer 6 such that the controller chip 3 is covered with the memory chip 5 is performed.

For bonding of the memory chip 5 to the surfaces of the controller chip 3, the first main spacer 41, the second main spacer 42, the first additional spacer 43, and the second additional spacer 44 via the adhesive layer 6, first, the memory chip 5 having the adhesive layer 6 laminated thereon is picked up. Then, while heat is applied to the adhesive layer 6, the memory chip 5 is pressed against the adhesive layer 6 and thereby onto the surfaces of the controller chip 3, the first main spacer 41, the second main spacer 42, the first additional spacer 43, and the second additional spacer 44. Note that the pickup of the controller chip 3, the application of heat to the adhesive layer 6, and the pressing of the memory chip 5 to the surfaces of the controller chip 3, the first main spacer 41, the second main spacer 42, the first additional spacer 43, and the second additional spacer 44 can be performed by known methods. Thus, the details will not be described herein.

In the production of the semiconductor device 1, next, a step of curing the adhesive layer 6 is performed. Since the curing of the adhesive layer 6 can be performed by a known method, the details will not be described herein.

In the production of the semiconductor device 1, next, a step of encapsulating the controller chip 3, the plurality of spacers 4, and the memory chip 5 over the substrate 2 with the encapsulation material 7 is performed. Note that, since the encapsulation with the encapsulation material 7 can be performed by a known method, the details will not be described herein. As a result, the semiconductor device 1 is obtained.

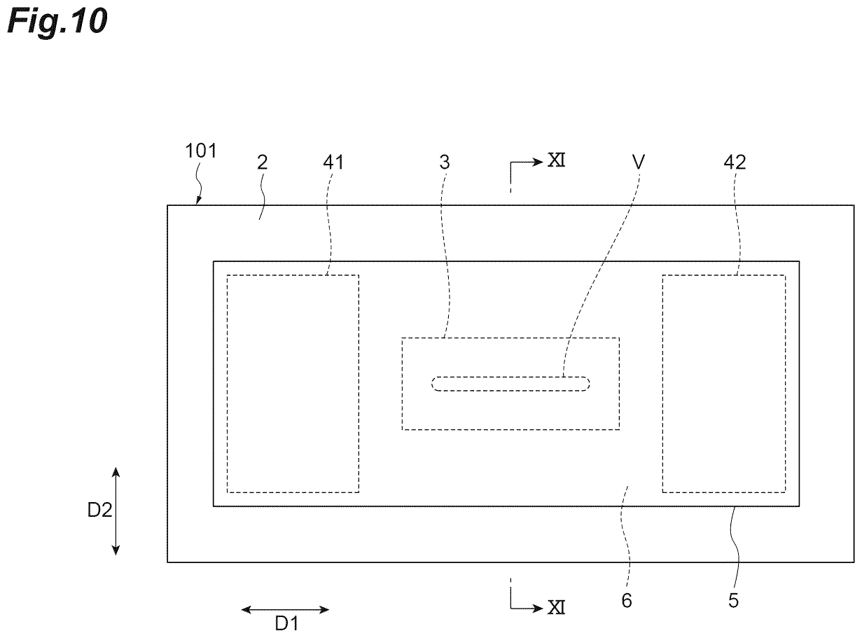

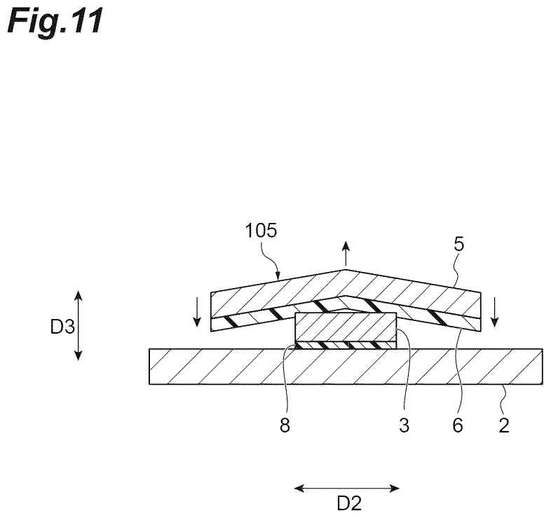

Here, a semiconductor device 1 of a comparative example will be described. FIG. 10 is a schematic plan view illustrating a semiconductor device of a comparative example. FIG. 11 is a schematic cross-sectional view taken along line XI-XI in FIG. 10. A semiconductor device 101 of the comparative example illustrated in FIGS. 10 and 11 is substantially similar to the semiconductor device 1 described above, but is different from the semiconductor device 1 described above only in that the first additional spacer 43 and the second additional spacer 44 are not provided.

Since the semiconductor device 101 of the comparative example does not include the first additional spacer 43 and the second additional spacer 44 of the semiconductor device 1, the memory chip 5 and the adhesive layer 6 tend to sag downward toward the substrate 2 at both sides of the controller chip 3 in the lateral direction D2 during the production of the semiconductor device 101. When the memory chip 5 and the adhesive layer 6 sag downward in this manner, the adhesive layer 6 tends to lift off from the controller chip 3 at the central portion of the controller chip 3 in the lateral direction D2. As a result, a void V extending in the longitudinal direction D1 of the controller chip 3 is likely to occur at the central portion of the controller chip 3 in the lateral direction D2 between the memory chip 5 and the adhesive layer 6.

In contrast, in the semiconductor device 1 of the present disclosure, not only the first main spacer 41 and the second main spacer 42 are disposed on both sides of the controller chip 3 in the longitudinal direction D1 of the controller chip 3, but also the first additional spacer and the second additional spacer are disposed on both sides of the controller chip 3 in the lateral direction D2 of the controller chip 3. Therefore, during the production of the semiconductor device 1, it is possible to minimize not only downward sagging of the memory chip 5 and the adhesive layer 6 toward the substrate 2 at both sides of the controller chip 3 in the longitudinal direction D1, but also downward sagging of the memory chip 5 and the adhesive layer 6 toward the substrate 2 at both sides of the controller chip 3 in the lateral direction D2. As a result, it is possible to suppress the occurrence of a void between the controller chip 3 and the adhesive layer 6.

Similarly, in the method for producing the semiconductor device 1 of the present disclosure, not only the first main spacer 41 and the second main spacer 42 are disposed on both sides of the controller chip 3 in the longitudinal direction D1 of the controller chip 3, but also the first additional spacer 43 and the second additional spacer 44 are disposed on both sides of the controller chip 3 in the lateral direction D2 of the controller chip 3. Therefore, it is possible to minimize not only downward sagging of the memory chip 5 and the adhesive layer 6 toward the substrate 2 at both sides of the controller chip 3 in the longitudinal direction D1, but also downward sagging of the memory chip 5 and the adhesive layer 6 toward the substrate 2 at both sides of the controller chip 3 in the lateral direction D2. As a result, it is possible to suppress the occurrence of a void between the controller chip 3 and the adhesive layer 6.

In addition, since the length L4 of each of the first additional spacer 43 and the second additional spacer 44 in the longitudinal direction D1 is 80% or more and 120% or less of the length L1 of the controller chip 3 in the longitudinal direction D1, it is possible to appropriately minimize downward sagging of the memory chip 5 and the adhesive layer 6 toward the substrate 2 at both sides of the controller chip 3 in the lateral direction D2 during the production of the semiconductor device 1. As a result, it is possible to yet further suppress the occurrence of a void between the controller chip 3 and the adhesive layer 6.

In addition, since the separation distance G2 between the controller chip 3 and each of the first additional spacer 43 and the second additional spacer 44 is shorter than the separation distance G1 between the controller chip 3 and each of the first main spacer 41 and the second main spacer 42, the first additional spacer 43 and the second additional spacer 44 can be easily disposed between the substrate 2 and the memory chip 5 even in a case where the memory chip 5 is short in the lateral direction D2.

Furthermore, since the first additional spacer 43 and the second additional spacer 44 extend beyond the memory chip 5 in the lateral direction D2 in plan view, the first additional spacer 43 and the second additional spacer 44 can be easily disposed between the substrate 2 and the memory chip 5 even in a case where the memory chip 5 is short in the lateral direction D2.

Here, the present inventors evaluated the occurrence of a void between the controller chip 3 and the adhesive layer 6 by varying the height of the controller chip 3 with respect to the substrate 2, the heights of the first main spacer 41 and the second main spacer 42 with respect to the substrate 2, and the heights of the first additional spacer 43 and the second additional spacer 44 with respect to the substrate 2. As a result, it has been found that the occurrence of a void between the memory chip and the adhesive layer 6 is further suppressed when the height H3 of each of the first additional spacer 43 and the second additional spacer 44 with respect to the substrate 2 is equal to or higher than the height H1 of the controller chip 3 with respect to the substrate 2, and the occurrence of a void between the memory chip 5 and the adhesive layer 6 is further suppressed when the height H3 of each of the first additional spacer 43 and the second additional spacer 44 with respect to the substrate 2 is higher than the height H1 of the controller chip 3 with respect to the substrate 2.

From such findings, it is more preferable that the height H3 of each of the first additional spacer 43 and the second additional spacer 44 with respect to the substrate 2 is equal to or higher than the height H1 of the controller chip 3 with respect to the substrate 2, and it is still more preferable that the height H3 of each of the first additional spacer 43 and the second additional spacer 44 with respect to the substrate 2 is higher than the height H1 of the controller chip 3 with respect to the substrate 2. Since the height H3 of each of the first additional spacer 43 and the second additional spacer 44 with respect to the substrate 2 is equal to or higher than the height H1 of the controller chip 3 with respect to the substrate 2, the occurrence of a void between the memory chip 5 and the adhesive layer 6 can be more suppressed. Furthermore, since the height H3 of each of the first additional spacer 43 and the second additional spacer 44 with respect to the substrate 2 is higher than the height H1 of the controller chip 3 with respect to the substrate 2, it is possible to yet further suppress the occurrence of a void between the memory chip 5 and the adhesive layer 6.

The gist of the present disclosure is as follows [1] to [7].
[1] A semiconductor device including: a substrate; a first semiconductor chip having a rectangular shape and disposed over the substrate; a plurality of spacers disposed around the first semiconductor chip over the substrate; a second semiconductor chip facing the substrate to cover the first semiconductor chip; and an adhesive layer provided on a surface of the second semiconductor chip to face the first semiconductor chip, and bonded to the first semiconductor chip and the plurality of spacers, in which the plurality of spacers include a first main spacer and a second main spacer disposed on both sides of the first semiconductor chip in a longitudinal direction of the first semiconductor chip, and a first additional spacer and a second additional spacer disposed on both sides of the first semiconductor chip in a lateral direction of the first semiconductor chip.
[2] The semiconductor device according to [1], in which a height of each of the first additional spacer and the second additional spacer with respect to the substrate is equal to or higher than a height of the first semiconductor chip with respect to the substrate.
[3] The semiconductor device according to [1], in which a height of each of the first additional spacer and the second additional spacer with respect to the substrate is higher than a height of the first semiconductor chip with respect to the substrate.
[4] The semiconductor device according to any one of [1] to [3], in which a length of each of the first additional spacer and the second additional spacer in the longitudinal direction is 80% or more and 120% or less of a length of the first semiconductor chip in the longitudinal direction.
[5] The semiconductor device according to any one of [1] to [4], in which a separation distance between the first semiconductor chip and each of the first additional spacer and the second additional spacer is shorter than a separation distance between the first semiconductor chip and each of the first main spacer and the second main spacer.
[6] The semiconductor device according to any one of [1] to [5], in which the first additional spacer and the second additional spacer extend beyond the second semiconductor chip in the lateral direction in plan view.
[7] A method for producing a semiconductor device, the method including: a step of bonding, onto a substrate, a first semiconductor chip having a rectangular shape, a first main spacer and a second main spacer disposed on both sides of the first semiconductor chip in a longitudinal direction of the first semiconductor chip, and a first additional spacer and a second additional spacer disposed on both sides of the first semiconductor chip in a lateral direction of the first semiconductor chip; a step of laminating an adhesive layer in an uncured state onto one surface of a second semiconductor chip; a step of bonding the second semiconductor chip to surfaces of the first semiconductor chip, the first main spacer, the second main spacer, the first additional spacer, and the second additional spacer via the adhesive layer such that the first semiconductor chip is covered with the second semiconductor chip; and a step of curing the adhesive layer.

### EXAMPLES

Hereinafter, examples of the present disclosure will be described. Note that the present disclosure is not limited to the following examples.

### EXAMPLES

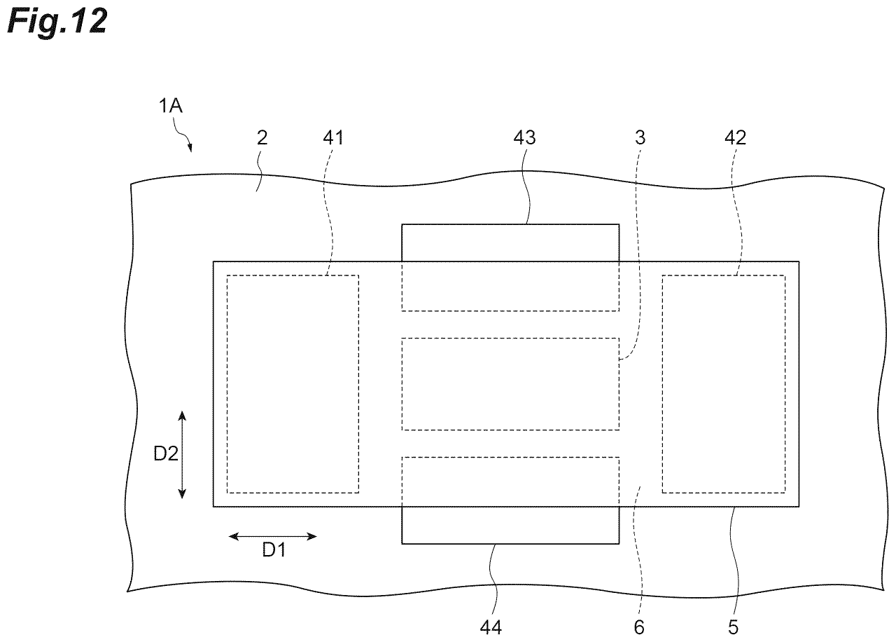

A semiconductor device 1A illustrated in FIG. 12 was prepared as a semiconductor device of an example. FIG. 12 is a schematic plan view illustrating a semiconductor device of the example. As illustrated in FIG. 12, first, the controller chip 3 having a rectangular shape, the first main spacer 41 and the second main spacer 42 disposed on both sides of the controller chip 3 in the longitudinal direction D1 of the controller chip 3, and the first additional spacer 43 and the second additional spacer 44 disposed on both sides of the controller chip 3 in the lateral direction D2 of the controller chip 3 were bonded to the substrate 2. In addition, the adhesive layer 6 in an uncured state was laminated onto one surface of the memory chip 5.

The length of the controller chip 3 in the longitudinal direction D1 was 4.5 mm, and the length of the controller chip 3 in the lateral direction D2 was 1.6 mm. The length of each of the first main spacer 41 and the second main spacer 42 in the longitudinal direction D1 was 2.5 mm, and the length of each of the first main spacer 41 and the second main spacer 42 in the lateral direction D2 was 3.6 mm. The length of each of the first additional spacer 43 and the second additional spacer 44 in the longitudinal direction D1 was 4.5 mm, and the length of each of the first additional spacer 43 and the second additional spacer 44 in the lateral direction D2 was 1.6 mm.

The separation distance between the controller chip 3 and each of the first main spacer 41 and the second main spacer 42 in the longitudinal direction D1 was 1.0 mm. The separation distance between the controller chip 3 and each of the first additional spacer 43 and the second additional spacer 44 in the lateral direction D2 was 0.6 mm.

When viewed from the longitudinal direction D1, both end portions of each of the first main spacer 41 and the second main spacer 42 in the lateral direction D2 extend beyond the controller chip 3 in the lateral direction D2. A position of each of the first additional spacer 43 and the second additional spacer 44 in the longitudinal direction D1 was the same as the position of the controller chip 3 in the longitudinal direction D1.

Next, the memory chip 5 was bonded to the surfaces of the controller chip 3, the first main spacer 41, the second main spacer 42, the first additional spacer 43, and the second additional spacer 44 via the adhesive layer 6 such that the controller chip 3 was covered with the memory chip 5 and the first additional spacer 43 and the second additional spacer 44 extended beyond the memory chip 5 in the lateral direction D2 in plan view. This bonding was performed by picking up the controller chip 3 onto which the adhesive layer 6 was laminated, and pressing the controller chip 3 against the adhesive layer 6 and thereby onto the surfaces of the controller chip 3, the first main spacer 41, the second main spacer 42, the first additional spacer 43, and the second additional spacer 44 while heating was applied to the adhesive layer 6. Thus, the semiconductor device of the example was obtained. In the semiconductor device of the example, the adhesive layer 6 was not cured.

### Example 1

In the semiconductor device of the above-described example, the height of the controller chip 3 with respect to the substrate 2 was set to 85 μm, the height of each of the first main spacer 41 and the second main spacer 42 with respect to the substrate 2 was set to 75 μm, and the height of each of the first additional spacer 43 and the second additional spacer 44 with respect to the substrate 2 was set to 75 μm. Then, the conditions for bonding the memory chip 5 to the surfaces of the controller chip 3, the first main spacer 41, the second main spacer 42, the first additional spacer 43, and the second additional spacer 44 via the adhesive layer 6 were set to a temperature of 140° C., a load of 1.47 MPa, and a time of 1.5 seconds, and four semiconductor devices of Example 1 were prepared.

### Example 2

Four semiconductor devices of Example 2 were prepared under the same conditions as in Example 1, except that the conditions for bonding the memory chip 5 to the surfaces of the controller chip 3, the first main spacer 41, the second main spacer 42, the first additional spacer 43, and the second additional spacer 44 via the adhesive layer 6 were set to a temperature of 120° C., a load of 0.49 MPa, and a time of 1.5 seconds.

### Example 3

Four semiconductor devices of Example 3 were prepared under the same conditions as in Example 1, except that the height of the controller chip 3 with respect to the substrate 2 was set to 75 μm.

### Example 4

Four semiconductor devices of Example 4 were prepared under the same conditions as in Example 3, except that the conditions for bonding the memory chip 5 to the surfaces of the controller chip 3, the first main spacer 41, the second main spacer 42, the first additional spacer 43, and the second additional spacer 44 via the adhesive layer 6 were set to a temperature of 120° C., a load of 0.49 MPa, and a time of 1.5 seconds.

### Example 5

Four semiconductor devices of Example 5 were prepared under the same conditions as in Example 1, except that the height of the controller chip 3 with respect to the substrate 2 was set to 65 μm.

### Example 6

Four semiconductor devices of Example 6 were prepared under the same conditions as in Example 5, except that the conditions for bonding the memory chip 5 to the surfaces of the controller chip 3, the first main spacer 41, the second main spacer 42, the first additional spacer 43, and the second additional spacer 44 via the adhesive layer 6 were set to a temperature of 120° C., a load of 0.49 MPa, and a time of 1.5 seconds.

### COMPARATIVE EXAMPLE

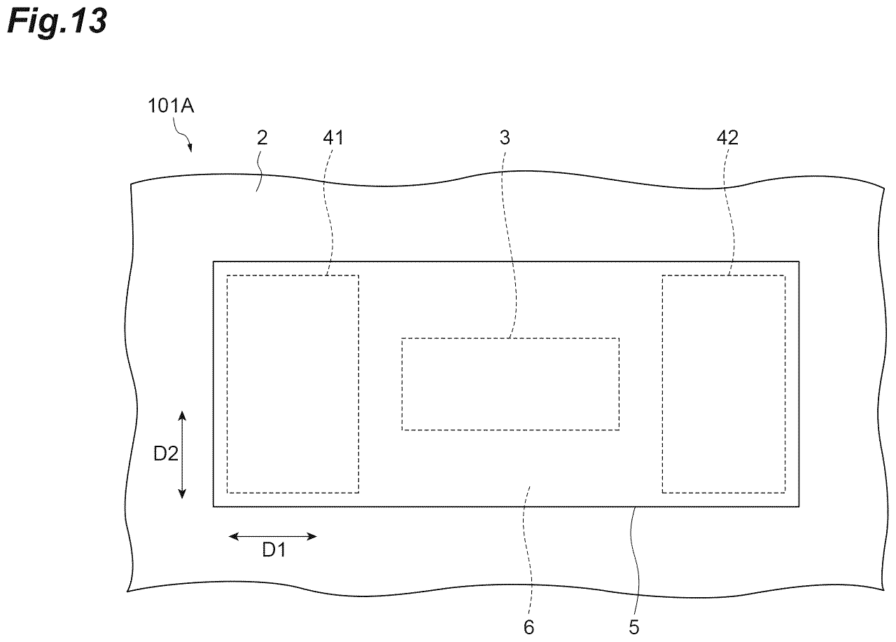

A semiconductor device 101A illustrated in FIG. 13 was prepared as a semiconductor device of a comparative example. FIG. 13 is a schematic plan view illustrating a semiconductor device of the comparative example. As illustrated in FIG. 13, the semiconductor device of the comparative example was produced in the same manner as the semiconductor device of the example, except that the first additional spacer 43 and the second additional spacer 44 were not provided. That is, first, the controller chip 3 having a rectangular shape and the first main spacer 41 and the second main spacer 42 disposed on both sides of the controller chip 3 in the longitudinal direction D1 of the controller chip 3 were bonded onto the substrate 2. In addition, the adhesive layer 6 in an uncured state was laminated onto one surface of the memory chip 5. Next, the memory chip 5 was bonded to the surfaces of the controller chip 3, the first main spacer 41, and the second main spacer 42 via the adhesive layer 6 such that the controller chip 3 is covered with the memory chip 5. Thus, the semiconductor device of the comparative example was obtained. Note that, in the semiconductor device of the comparative example, the adhesive layer 6 was not cured.

### Comparative Example 1

In the semiconductor device of the above-described comparative example, the height of the controller chip 3 with respect to the substrate 2 was set to 85 μm, and the height of each of the first main spacer 41 and the second main spacer 42 with respect to the substrate 2 was set to 75 μm. Then, the conditions for bonding the memory chip 5 to the surfaces of the controller chip 3, the first main spacer 41, and the second main spacer 42 via the adhesive layer 6 were set to a temperature of 140° C., a load of 1.79 MPa, and a time of 1.5 seconds, and four semiconductor devices of Comparative Example 1 were prepared.

### Comparative Example 2

Under the same conditions as in Comparative Example 1, four semiconductor devices of Comparative Example 2 were prepared, except that the conditions for bonding the memory chip 5 to the surfaces of the controller chip 3, the first main spacer 41, and the second main spacer 42 via the adhesive layer 6 were set to a temperature of 120° C., a load of 0.60 MPa, and a time of 1.5 seconds.

### Comparative Example 3

Two semiconductor devices of Comparative Example 3 were prepared under the same conditions as in Comparative Example 1, except that the height of the controller chip 3 with respect to the substrate 2 was set to 75 μm.

### Comparative Example 4

Under the same conditions as in Comparative Example 3, two semiconductor devices of Comparative Example 4 were prepared, except that the conditions for bonding the memory chip 5 to the surfaces of the controller chip 3, the first main spacer 41, and the second main spacer 42 via the adhesive layer 6 were set to a temperature of 120° C., a load of 0.60 MPa, and a time of 1.5 seconds.

### Comparative Example 5

Four semiconductor devices of Comparative Example 5 were prepared under the same conditions as in Comparative Example 1, except that the height of the controller chip 3 with respect to the substrate 2 was set to 65 μm.

### Comparative Example 6

Under the same conditions as in Comparative Example 5, four semiconductor devices of Comparative Example 6 were prepared, except that the conditions for bonding the memory chip 5 to the surfaces of the controller chip 3, the first main spacer 41, and the second main spacer 42 via the adhesive layer 6 were set to a temperature of 120° C., a load of 0.60 MPa, and a time of 1.5 seconds.

### (Evaluation)

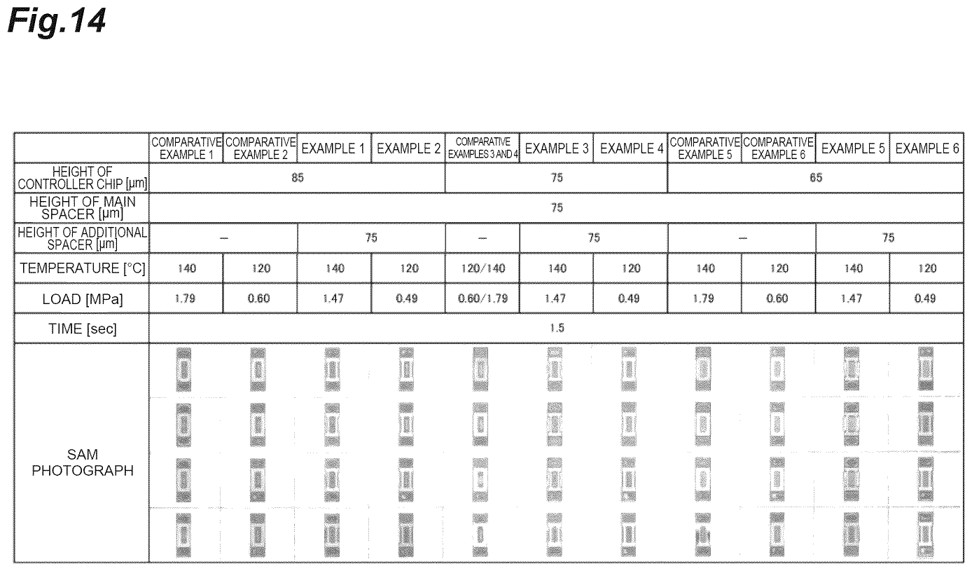

The semiconductor devices of Examples 1 to 6 and Comparative Examples 1 to 6 were analyzed using an ultrasonic microscope (SAM: Ultrasonic digital image diagnostic system IS-450 manufactured by Insight k.k.) to evaluate the occurrence of a void. In the evaluation, a case where no void occurred was determined as OK, and a case where a void occurred was determined as NG, and an OK proportion (the number of semiconductor devices determined as OK/the total number of semiconductor devices×100) was calculated. In addition, a case where no void occurred in all the semiconductor devices was evaluated as A, a case where no void occurred in some of the semiconductor devices was evaluated as B, a case where voids occurred in all the semiconductor devices but none of the voids were large was evaluated as C, and a case where voids occurred in all the semiconductor devices and there were large voids was evaluated as D. SAM photographs of the semiconductor devices of Examples 1 to 6 and Comparative Examples 1 to 6 are illustrated in FIG. 14, and the results thereof are illustrated in Table 1. Note that, in FIG. 14, Comparative Example 3 and Comparative Example 4 are illustrated in the same column, but the SAM photograph of Comparative Example 3 is the lower two of the four SAM photographs of the column, and the SAM photograph of Comparative Example 4 is the upper two of the four SAM photographs of the column.

TABLE 1

| | Compar- | Compar- | | | Compar- | Compar- | | | Compar- | Compar- | | |
|---|---|---|---|---|---|---|---|---|---|---|---|---|
| | ative | ative | | | ative | ative | | | ative | ative | | |
| | Exam- | Exam- | Exam- | Exam- | Exam- | Exam- | Exam- | Exam- | Exam- | Exam- | Exam- | Exam- |
| | ple 1 | ple 2 | ple 1 | ple 2 | ple 3 | ple 4 | ple 3 | ple 4 | ple 5 | ple 6 | ple 5 | ple 6 |
| Height of | 85 | | | | 75 | | | | 65 | | | |
| controller | | | | | | | | | | | | |
| chip [μm] | | | | | | | | | | | | |
| Height of | 75 | | | | | | | | | | | |
| main spacer | | | | | | | | | | | | |
| [μm] | | | | | | | | | | | | |
| Height of | — | | 75 | | — | | 75 | | — | | 75 | |
| additional | | | | | | | | | | | | |
| spacer [μm] | | | | | | | | | | | | |
| Temperature | 140 | 120 | 140 | 120 | 140 | 120 | 140 | 120 | 140 | 120 | 140 | 120 |
| [°C] | | | | | | | | | | | | |
| Load | 1.79 | 0.60 | 1.47 | 0.49 | 1.79 | 0.60 | 1.47 | 0.49 | 1.79 | 0.60 | 1.47 | 0.49 |
| [MPa] | | | | | | | | | | | | |
| Time | 1.5 | | | | | | | | | | | |
| [sec] | | | | | | | | | | | | |
| OK proportion | 0 | 0 | 0 | 0 | 0 | 0 | 0 | 50 | 0 | 0 | 100 | 100 |
| [%] | | | | | | | | | | | | |
| Void | D | D | C | C | D | D | C | A | D | D | A | A |
| evaluation | | | | | | | | | | | | |

As illustrated in Table 1, all of Comparative Examples 1 to 6 were evaluated as D, whereas all of Examples 1 to 6 were not evaluated as D, and were evaluated as A to C. In addition, in Comparative Examples 1 to 6, the OK proportion was 0% in all cases, whereas in Example 4, the OK proportion was 50%, and in Examples 5 and 6, the OK proportion was 100%. From these results, it has been found that the occurrence of a void between the first semiconductor chip and the adhesive layer can be suppressed by providing the first additional spacer and the second additional spacer. In addition, it has been found that occurrence of a large void is suppressed even in a case where a void occurred between the first semiconductor chip and the adhesive layer.

### Example 7

In the semiconductor device of the above-described example, the height of the controller chip 3 with respect to the substrate 2 was set to 65 μm, the height of each of the first main spacer 41 and the second main spacer 42 with respect to the substrate 2 was set to 75 μm, and the height of each of the first additional spacer 43 and the second additional spacer 44 with respect to the substrate 2 was set to 65 μm. Then, the conditions for bonding the memory chip 5 to the surfaces of the controller chip 3, the first main spacer 41, the second main spacer 42, the first additional spacer 43, and the second additional spacer 44 via the adhesive layer 6 were set to a temperature of 120° C., a load of 0.49 MPa, and a time of 1.5 seconds, and four semiconductor devices of Example 7 were prepared.

### Example 8

Four semiconductor devices of Example 8 were prepared under the same conditions as in Example 7, except that the heights of the first additional spacer 43 and the second additional spacer 44 with respect to the substrate 2 were set to 75 μm.

### Example 9

Four semiconductor devices of Example 9 were prepared under the same conditions as in Example 7, except that the heights of the first additional spacer 43 and the second additional spacer 44 with respect to the substrate 2 were set to 85 μm.

### Example 10

Four semiconductor devices of Example 10 were prepared under the same conditions as in Example 7, except that the height of the controller chip 3 with respect to the substrate 2 was set to 75 μm.

### Example 11

Four semiconductor devices of Example 11 were prepared under the same conditions as in Example 10, except that the heights of the first additional spacer 43 and the second additional spacer 44 with respect to the substrate 2 were set to 75 μm.

### Example 12

Four semiconductor devices of Example 12 were prepared under the same conditions as in Example 10, except that the heights of the first additional spacer 43 and the second additional spacer 44 with respect to the substrate 2 were set to 85 μm.

### Example 13

Four semiconductor devices of Example 13 were prepared under the same conditions as in Example 7, except that the height of the controller chip 3 with respect to the substrate 2 was set to 85 μm.

### Example 14

Four semiconductor devices of Example 14 were prepared under the same conditions as in Example 13, except that the heights of the first additional spacer 43 and the second additional spacer 44 with respect to the substrate 2 were set to 75 μm.

### Example 15

Four semiconductor devices of Example 15 were prepared under the same conditions as in Example 13, except that the heights of the first additional spacer 43 and the second additional spacer 44 with respect to the substrate 2 were set to 85 μm.

### (Evaluation)

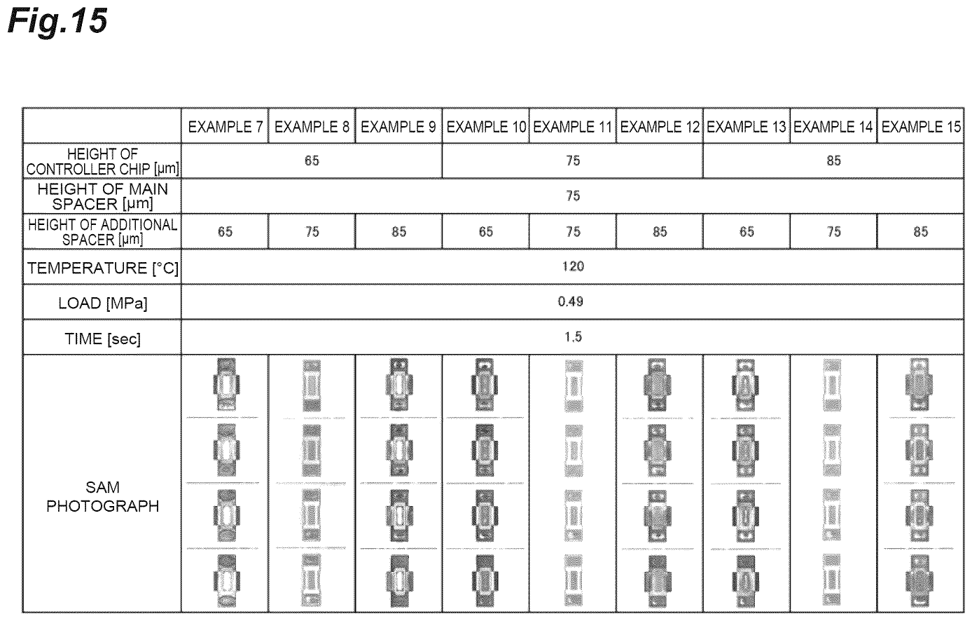

The semiconductor devices of Examples 7 to 15 were analyzed using an ultrasonic microscope (SAM: Ultrasonic digital image diagnostic system IS-450 manufactured by Insight k.k.) to evaluate the occurrence of a void. In the evaluation, a case where no void occurred was determined as OK, and a case where a void occurred was determined as NG, and an OK proportion (the number of semiconductor devices determined as OK/the total number of semiconductor devices×100) was calculated. In addition, a case where no void occurred in all the semiconductor devices was evaluated as A, a case where no void occurred in some of the semiconductor devices was evaluated as B, a case where voids occurred in all the semiconductor devices but none of the voids were large was evaluated as C, and a case where voids occurred in all the semiconductor devices and there were large voids was evaluated as D. SAM photographs of the semiconductor devices of Examples 7 to 15 are illustrated in FIG. 15, and the results thereof are illustrated in Table 2.

TABLE 2

| | Exam- | Exam- | Exam- | Exam- | Exam- | Exam- | Exam- | Exam- | Exam- |
|---|---|---|---|---|---|---|---|---|---|
| | ple 7 | ple 8 | ple 9 | ple 10 | ple 11 | ple 12 | ple 13 | ple 14 | ple 15 |
| Height of | 65 | | | 75 | | | 85 | | |
| controller | | | | | | | | | |
| chip [μm] | | | | | | | | | |
| Height of | 75 | | | | | | | | |
| main spacer | | | | | | | | | |
| [μm] | | | | | | | | | |
| Height of | 65 | 75 | 85 | 65 | 75 | 85 | 65 | 75 | 85 |
| additional | | | | | | | | | |
| spacer [μm] | | | | | | | | | |
| Temperature | 120 | | | | | | | | |
| [°C] | | | | | | | | | |
| Load | 0.49 | | | | | | | | |
| [MPa] | | | | | | | | | |
| Time | 1.5 | | | | | | | | |
| [sec] | | | | | | | | | |
| OK proportion | 25 | 100 | 100 | 0 | 50 | 100 | 0 | 0 | 0 |
| [%] | | | | | | | | | |
| Void | B | A | A | C | B | A | C | C | C |
| evaluation | | | | | | | | | |

As illustrated in Table 2, in Examples 7 to 15, all of Examples 7 to 15 were not evaluated as D, and were evaluated as A to C. Examples 10, 13, and 14 in which the heights of the additional spacers with respect to the substrate were less than the height of the controller chip with respect to the substrate were all evaluated as C. In contrast, among Examples 7 to 9, 11, 12, and 15 in which the heights of the additional spacers with respect to the substrate were equal to or higher than the height of the controller chip with respect to the substrate, Examples 7 to 9, 11, and 12 were evaluated as A or B without being evaluated as C. Furthermore, Examples 8, 9, and 12 in which the heights of the additional spacers with respect to the substrate were higher than the height of the controller chip with respect to the substrate were all evaluated as A.

From these results, it has been found that when the heights of the additional spacers with respect to the substrate are equal to or higher than the height of the controller chip with respect to the substrate, the occurrence of a void between the chip and the adhesive layer can be further suppressed. Furthermore, it has been found that when the heights of the additional spacers with respect to the substrate are higher than the height of the controller chip with respect to the substrate, the occurrence of a void between the controller chip and the adhesive layer can be yet further suppressed.

### REFERENCE SIGNS LIST

1 Semiconductor device
2 Substrate
3 Controller chip (first semiconductor chip)
4 Spacer
5 Memory chip (second semiconductor chip)
6 Adhesive layer
7 Encapsulation material
8 Adhesive layer
9 Adhesive layer
41 First main spacer
42 Second main spacer
43 First additional spacer
44 Second additional spacer
101 Semiconductor device
D1 Longitudinal direction
D2 Lateral direction
D3 Facing direction
G1 Separation distance
G2 Separation distance
V Void

1. A semiconductor device comprising:
a substrate;
a first semiconductor chip having a rectangular shape and disposed over the substrate;
a plurality of spacers disposed around the first semiconductor chip over the substrate;
a second semiconductor chip facing the substrate to cover the first semiconductor chip; and
an adhesive layer provided on a surface of the second semiconductor chip to face the first semiconductor chip, and bonded to the first semiconductor chip and the plurality of spacers,
wherein the plurality of spacers include
a first main spacer and a second main spacer disposed on both sides of the first semiconductor chip in a longitudinal direction of the first semiconductor chip, and
a first additional spacer and a second additional spacer disposed on both sides of the first semiconductor chip in a lateral direction of the first semiconductor chip.

2. The semiconductor device according to claim 1,
wherein a height of each of the first additional spacer and the second additional spacer with respect to the substrate is equal to or higher than a height of the first semiconductor chip with respect to the substrate.

3. The semiconductor device according to claim 1,
wherein a height of each of the first additional spacer and the second additional spacer with respect to the substrate is higher than a height of the first semiconductor chip with respect to the substrate.

4. The semiconductor device according to claim 1,
wherein a length of each of the first additional spacer and the second additional spacer in the longitudinal direction is 80% or more and 120% or less of a length of the first semiconductor chip in the longitudinal direction.

5. The semiconductor device according to claim 1,
wherein a separation distance between the first semiconductor chip and each of the first additional spacer and the second additional spacer is shorter than a separation distance between the first semiconductor chip and each of the first main spacer and the second main spacer.

6. The semiconductor device according to claim 1,
wherein the first additional spacer and the second additional spacer extend beyond the second semiconductor chip in the lateral direction in plan view.

7. A method for producing a semiconductor device, the method comprising:
bonding, onto a substrate, a first semiconductor chip having a rectangular shape, a first main spacer and a second main spacer disposed on both sides of the first semiconductor chip in a longitudinal direction of the first semiconductor chip, and a first additional spacer and a second additional spacer disposed on both sides of the first semiconductor chip in a lateral direction of the first semiconductor chip;
laminating an adhesive layer in an uncured state onto one surface of a second semiconductor chip;
bonding the second semiconductor chip to surfaces of the first semiconductor chip, the first main spacer, the second main spacer, the first additional spacer, and the second additional spacer via the adhesive layer such that the first semiconductor chip is covered with the second semiconductor chip; and
curing the adhesive layer.
